(19) United States
(12) Patent Application Publication
(10) Pub. No.: US 2026/0206102 A1
(43) Pub. Date: Jul. 16, 2026

(54) JACKET HEATER, METHOD FOR MANUFACTURING JACKET HEATER, AND HEATING UNIT

(71) Applicants: NICHIAS Corporation, Tokyo (JP); Thermos Corporation, Yamatokoriyama-shi, Nara (JP)

(72) Inventors: Akira SASAKI, Tokyo (JP); Keiichi FUKUDA, Tokyo (JP); Daisaku SEKI, Tokyo (JP); Kenji IIDA, Tokyo (JP); Susumu TAGUCHI, Nara (JP)

(21) Appl. No.: 19/156,895

(22) PCT Filed: Feb. 13, 2024
(86) PCT No.: PCT/JP2024/004754

§ 371 Date: Aug. 15, 2025

(30) Foreign Application Priority Data
Feb. 24, 2023 (JP) 2023-027154

(51) Int. Cl. H05B 3/58; F16L 53/38; F16L 59/02; H05B 1/02

(52) U.S. Cl. CPC H05B 3/58; F16L 53/38; H05B 1/0213; F16L 59/029

(57) ABSTRACT

A jacket heater in which, even when tensile force is applied to a cable part of a thermocouple, a wiring disconnection does not easily occur in the cable part, and the position of a temperature detection point is not easily displaced. A jacket heater is attached to a heated object for use, including an inner layer being in contact with the heated object; an outer layer; a heat generation layer between the inner layer and the outer layer; a thermal insulation layer between the heat generation layer and the outer layer; and a temperature sensor including a temperature detection point exposed to an inner surface of the inner layer being in contact with the heated object and a cable part extending from the temperature detection point. The cable part penetrates the inner layer, the heat generation layer, the thermal insulation layer, and the outer layer.

### RELATED APPLICATIONS

The present application is National Phase of International Application No. PCT/JP2024/004754 filed Feb. 13, 2024, and claims priority from Japanese Application No. 2023-027154, filed Feb. 24, 2023.

### TECHNICAL FIELD

The present invention is related to a jacket heater that is to be attached to a heated object for use, a method for manufacturing a jacket heater, and a heating unit.

### BACKGROUND ART

Manufacturing processes of semiconductor elements, Flat Panel Displays (FPDs), and the like include a deposition step and an etching step during which various types of process gases are used. In these steps, a by-product or an exhaust gas may be generated. It is known that, on the inside of a pipe for discharging such a by-product or an exhaust gas, the by-product or the exhaust gas may become solidified and precipitate.

To prevent the by-product or the exhaust gas from becoming solidified or precipitating inside the pipe, the pipe used for the discharging purpose may be provided with a heater for heating the pipe. The heater attached to the pipe may be referred to as a jacket heater (or a mantle heater) and is configured to heat the pipe while being in contact with the outer surface of the pipe (see Patent Literature 1, for example).

FIG. 9 is a perspective view of a jacket heater 1000 that is hitherto known. As shown in FIG. 9, the jacket heater 1000 includes an inner layer 1100 that is in contact with a pipe P serving as an object to be heated (hereinafter, “heated object”); and an outer layer 1200 structuring the outermost layer of the jacket heater 1000. Provided between the inner layer 1100 and the outer layer 1200 is a heat generation layer 1300 including a heating wire 1310 serving as a heat source. Provided between the outer layer 1200 and the heat generation layer 1300 is a thermal insulation layer 1400 that prevents heat generated from the heat generation layer 1300 from being released to the outside via the outer layer 1200. The jacket heater 1000 is configured so that the heat generation layer 1300 generates the heat as a result of electrical power (hereinafter, simply “power”) being supplied to the heating wire 1310, so as to heat the pipe P to which the jacket heater 1000 is attached.

Examples of jacket heaters structured as described above include a jacket heater provided with a thermocouple for detecting temperature of the heated object. The jacket heater provided with the thermocouple may be used while being connected to a power supply control mechanism (a power supply control device) that controls the power supply to the heating wire and is capable of adjusting the temperature of the heated object, on the basis of the temperature of the heated object detected by the thermocouple. In this manner, the heated object is maintained in a desired temperature range.

### CITATION LIST

### Patent Literature

Patent Literature 1: Japanese Patent Laid-Open No. 2002-295783

### SUMMARY OF INVENTION

### Technical Problem

Temperature sensors such as the thermocouple may be a temperature sensor including a temperature detection point and a cable part extending from the temperature detection point. The temperature of a measured object is detected as a result of an electrical signal corresponding to heat detected at the temperature detection point being transferred via the cable part. A problem with Jacket heaters using a temperature sensor such as a thermocouple including a cable part is that the position of the temperature detection point may be displaced or a wiring disconnection may occur in the cable part, due to tensile force being applied to the cable part at the time of attaching the jacket heater to the heated object or at the time of servicing or inspecting the jacket heater.

An object of the present invention is to provide a jacket heater in which, even when tensile force is applied to the cable part of the temperature sensor, a wiring disconnection does not easily occur in the cable part, and the position of the temperature detection point is not easily displaced.

### Solution to Problem

A gist of the present invention can be summarized as follows:
[1] A jacket heater that is to be attached to a heated object for use, including: an inner layer being in contact with the heated object; an outer layer; a heat generation layer and a thermal insulation layer provided between the inner layer and the outer layer; and a temperature sensor including a temperature detection point exposed to an inner surface of the inner layer being in contact with the heated object and a cable part extending from the temperature detection point. The cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.
[2] The jacket heater according to [1] in which the thermal insulation layer includes a first thermal insulation layer provided between the heat generation layer and the outer layer and a second thermal insulation layer provided between the first thermal insulation layer and a side of the outer layer; and the section of the cable part from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the inner layer, the heat generation layer, the first thermal insulation layer, the second thermal insulation layer, and the outer layer.
[3] A jacket heater that is to be attached to a heated object for use, including: an inner layer being in contact with the heated object; an outer layer; a heat generation layer and a thermal insulation layer provided between the inner layer and the outer layer; and a temperature sensor including a temperature detection point positioned between the inner layer and the heat generation layer and a cable part extending from the temperature detection point. The cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.
[4] The jacket heater according to [3] in which the thermal insulation layer includes a first thermal insulation layer provided between the heat generation layer and the outer layer and a second thermal insulation layer provided between the first thermal insulation layer and a side of the outer layer; and the section of the cable part from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-Substitute positioned layers including at least one of the heat generation layer, the first thermal insulation layer, the second thermal insulation layer, and the outer layer.
[5] The jacket heater according to [1] or [3] in which a section of the cable part positioned in an inter-layer space between the outer layer and the thermal insulation layer is positioned on the path bypassing the linear path connecting the derivation part to the introduction part.
[6] The jacket heater according to [1] or [3] in which the heat generation layer includes a heating wire as a heat source; and a heating wire cable connected to the heating wire penetrates the thermal insulation layer and the outer layer, starting with the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.
[7] The jacket heater according to [6] in which the thermal insulation layer includes a first thermal insulation layer provided between the heat generation layer and the outer layer and a second thermal insulation layer provided between the first thermal insulation layer and a side of the outer layer; and the section of the heating wire cable from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the heat generation layer, the first thermal insulation layer, the second thermal insulation layer, and the outer layer.
[8] The jacket heater according to [1] or [3] in which the temperature sensor is one of a thermocouple and a resistance thermometer.
[9] The jacket heater according to [1] in which the heat generation layer includes a heating wire as a heat source; and the temperature detection point of the temperature sensor is provided in a position that does not overlap with the heating wire, in a direction perpendicular to a contact surface between the heated object and the inner layer.
[10] The jacket heater according to [9] in which all the sections of the temperature sensor exposed to the inner surface of the inner layer are each provided in a position that does not overlap with the heating wire, in the direction perpendicular to the contact surface.
[11] The jacket heater according to [3] in which the heat generation layer includes a heating wire as a heat source; and the temperature detection point of the temperature sensor is provided in a position that does not overlap with the heating wire, in a direction perpendicular to a contact surface between the heated object and the inner layer.
[12] The jacket heater according to [11] in which all the sections of the temperature sensor positioned between the inner layer and the heat generation layer are each provided in a position that does not overlap with the heating wire, in the direction perpendicular to the contact surface.
[13] The jacket heater according to [1] or [3] in which the heat generation layer includes a heating wire as a heat source; the jacket heater further includes a thermostat; and a temperature detection point of the thermostat is provided in a position that does not overlap with the heating wire, in a direction perpendicular to a contact surface between the heated object and the inner layer.
[14] The jacket heater according to [13] in which the heating wire extends while being folded back and forth within the heat generation layer so as to form rows arranged in a prescribed direction; and the thermostat is arranged so as to be surrounded by folded parts of the heating wire.
[15] The jacket heater according to [1] or [3] in which the jacket heater further includes a thermostat; the thermal insulation layer is formed so as to be fitted along an exterior shape of the thermostat; and an accommodation part forming a space for accommodating the thermostat therein is provided.
[16] The jacket heater according to [15] in which the accommodation part is a through hole penetrating the thermal insulation layer.
[17] The jacket heater according to [15] in which the accommodation part is a recessed part that opens toward the heated object.
[18] The jacket heater according to [15] in which the heat generation layer includes a heating wire as a heat source; the heating wire is arranged according to a prescribed arrangement pattern on a surface of the thermal insulation layer; and a part of the heating wire is arranged along the accommodation part in a position apart from the accommodation part by a prescribed distance.
[19] The jacket heater according to [15] in which the heat generation layer includes a heating wire serving as a heat source and a supporting member to which the heating wire is fixed; the supporting member has an opening part penetrated by the thermostat; and a flange part provided for the thermostat is attached to the supporting member.
[20] The jacket heater according to [19] in which the supporting member is an inorganic fiber sheet; and an edge of the opening part is sewn by using a reinforcement thread.
[21] A method for manufacturing a jacket heater that is to be attached to a heated object for use, including a step of forming a laminated body which includes an inner layer being in contact with the heated object, an outer layer, as well as a heat generation layer and a thermal insulation layer provided between the inner layer and the outer layer, the laminated body having fixed thereto a temperature sensor including a temperature detection point and a cable part extending from the temperature detection point. The temperature detection point is exposed to an inner surface of the inner layer; and the cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.
[22] A method for manufacturing a jacket heater that is to be attached to a heated object for use, including: a step of forming a laminated body which includes an inner layer being in contact with the heated object, an outer layer, as well as a heat generation layer and a thermal insulation layer provided between the inner layer and the outer layer, the laminated body having fixed thereto a temperature sensor including a temperature detection point and a cable part extending from the temperature detection point. The temperature detection point is positioned between the inner layer and the heat generation layer; and the cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.
[23] A heating unit that covers a pipe and heats an inside of the pipe, including: an inner layer being in contact with a heated object; an outer layer; a heat generation layer and a thermal insulation layer provided between the inner layer and the outer layer; and a temperature sensor including a temperature detection point exposed to an inner surface of the inner layer being in contact with the heated object and a cable part extending from the temperature detection point. The cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.
[24] A heating unit that covers a pipe and heats an inside of the pipe, including: an inner layer being in contact with a heated object; an outer layer; a heat generation layer and a thermal insulation layer provided between the inner layer and the outer layer; and a temperature sensor including a temperature detection point positioned between the inner layer and the heat generation layer and a cable part extending from the temperature detection point. The cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.

### Advantageous Effects of Invention

According to the present invention, it is possible to provide the jacket heater in which, even when tensile force is applied to the cable part of the temperature sensor, a wiring disconnection does not easily occur in the cable part, and the position of the temperature detection point is not easily displaced.

### BRIEF DESCRIPTION OF DRAWINGS

FIG. 1 is a perspective view of a jacket heater 100 according to a first embodiment.

FIG. 2 is a cross-sectional view taken at A-A′ of the jacket heater 100 shown in FIG. 1.

FIG. 3 is a drawing showing a situation in which tensile force is applied to a cable part 152 of the jacket heater 100 shown in FIG. 2.

FIG. 4 is an unfolded view of the jacket heater 100 shown in FIG. 1.

FIG. 5 shows a first modification example of the jacket heater 100 according to the first embodiment.

FIG. 6 shows a second modification example of the jacket heater 100 according to the first embodiment.

FIG. 7 shows a third modification example of the jacket heater 100 according to the first embodiment.

FIG. 8 shows a sixth modification example of the jacket heater 100 according to the first embodiment.

FIG. 9 is a perspective view of the conventional jacket heater 1000.

FIG. 10 is a perspective view of the jacket heater 100 according to a second embodiment.

FIG. 11 is a drawing for explaining a structure of a thermocouple.

FIG. 12A is a drawing for explaining a structure of a thermostat 160.

FIG. 12B is a drawing for explaining another structure of the thermostat 160.

FIG. 13 is a cross-sectional view taken at A-A′ of the jacket heater 100 shown in FIG. 10.

FIG. 14 is an unfolded view of the jacket heater 100 shown in FIG. 10.

FIG. 15 is a drawing showing the jacket heater 100 connected to a power supply control device.

FIG. 16 is a side view of the thermostat 160 provided for the jacket heater 100 according to a third embodiment.

FIG. 17 is a bottom view of the thermostat 160 provided for the jacket heater 100 according to the third embodiment.

FIG. 18 is a cross-sectional view showing a structure in which the thermostat 160 is embedded in the jacket heater 100 according to the third embodiment.

FIG. 19 is a schematic diagram of a thermal insulation layer 140 showing a part accommodating the thermostat 160.

FIG. 20 is a drawing for explaining a structure in which the thermostat 160 is fixed to a supporting member 132 and a positional relationship between the thermostat 160 and a heating wire 131.

FIG. 21 is another drawing for explaining the structure in which the thermostat 160 is fixed to the supporting member 132 and the positional relationship between the thermostat 160 and the heating wire 131.

### DESCRIPTION OF EMBODIMENTS

### First Embodiment

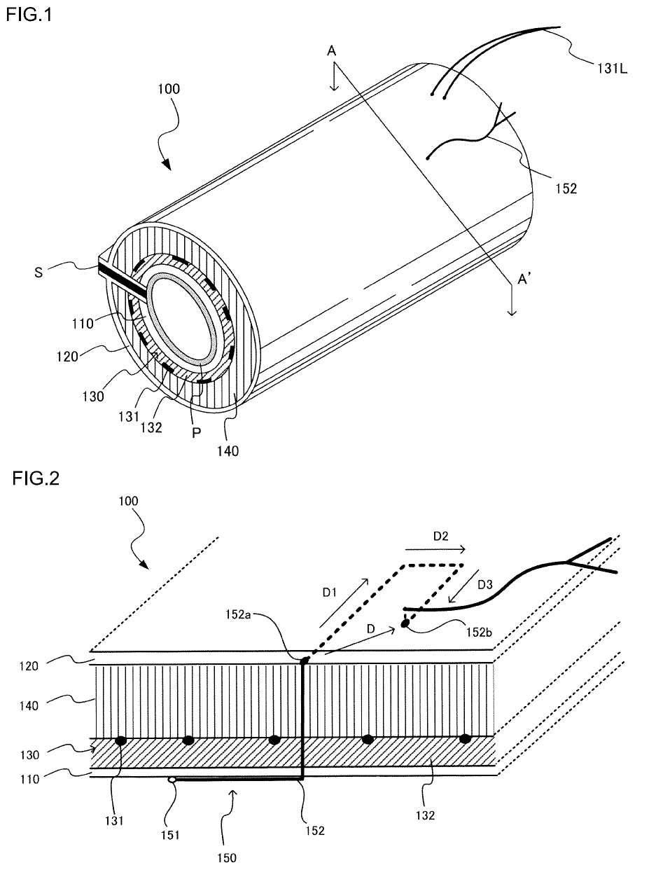

The following will describe an embodiment of the present invention, with reference to FIGS. 1 to 4. Although a jacket heater 100 will be explained in the following embodiment, the present invention is not limited to the jacket heater 100, as long as a heating unit covers a pipe and is capable of heating the inside of the pipe.

As shown in FIG. 1, the jacket heater 100 of the present embodiment includes an inner layer 110 and an outer layer 120. The inner layer 110 is a layer structuring the innermost layer of the jacket heater 100 and is in contact with a pipe P serving as a heated object. The outer layer 120 is a layer structuring the outermost layer of the jacket heater 100. Provided between the inner layer 110 and the outer layer 120 is a heat generation layer 130. Provided between the heat generation layer 130 and the outer layer 120 is a thermal insulation layer 140. The heat generation layer 130 includes a heat source and is configured to generate heat due to heat from the heat source. The thermal insulation layer 140 is configured to prevent the heat generated from the heat generation layer 130 from being released to the outside via the outer layer 120. In this situation, it is sufficient as long as the heat generation layer 130 and the thermal insulation layer 140 are provided between the inner layer 110 and the outer layer 120, and possible embodiments are not limited to the example shown in FIG. 1.

Formed on the inside of the jacket heater 100 is an accommodation space capable of accommodating therein the pipe P serving as the heated object. To make it possible to accommodate the pipe P in the accommodation space, the jacket heater 100 is provided with a slit S extending from the outer surface of the jacket heater 100 to the accommodation space. The jacket heater 100 has the pipe P accommodated in the accommodation space via the slit S and is attached by being fixed to the pipe P with the use of fixation means (not shown) such as a belt.

It is sufficient as long as the inner layer 110 and the outer layer 120 are each structured by using a material that can withstand the heat transferred from the heat generation layer 130. Although the material thereof is not particularly limited, possible examples that can be used include: a fluororesin sheet including a fluorine-based resin such as polytetrafluoroethylene (PTFE), a tetrafluoroethylene-perfluoroalkoxyethylene copolymer (PFA), a tetrafluoroethylene-hexafluoropropylene copolymer (FEP), polychlorotrifluoroethylene (PCTFE), a tetrafluoroethylene-ethylene copolymer (ETFE), a chlorotrifluoroethylene-ethylene copolymer (ECTFE), or polyvinylidene fluoride (PVDF); a fluororesin fiber cloth (a woven cloth) obtained by weaving fibers of any of the aforementioned fluorine-based resins; an inorganic fiber cloth (a woven cloth) including inorganic fibers such as glass fibers, silica fibers, alumina fibers, or silica alumina fibers; a fluororesin-coated inorganic fiber cloth obtained by coating the aforementioned inorganic fiber cloth with any of the aforementioned fluorine-based resins; and a silicone resin-coated inorganic fiber cloth obtained by coating the aforementioned inorganic fiber cloth with a silicone resin.

Alternatively, the inner layer 110 and the outer layer 120 may be structured by using a material other than the aforementioned fluorine-based resins and may be structured by using, for example, polyamide, polycarbonate, polyacetal, polybutylene terephthalate, modified polyphenylene ether, polyphenylene sulfide, polysulfone, polyethersulfone, polyarylate, polyether ether ketone, polyphthalamide, polyimide, polyetherimide, or polymethylpentene.

The heat generation layer 130 includes the heat source. As shown in FIG. 1, a heating wire 131 may be used as the heat source. While being connected to a heating wire cable 131C, the heating wire 131 penetrates the thermal insulation layer 140 and the outer layer 120, starting with the heat generation layer 130 toward the outer layer 120, so that a part thereof including an end part is exposed from the outer surface of the outer layer 120. The heating wire 131 generates the heat by receiving the power supply via the heating wire cable 131C. It is sufficient as long as the heating wire 131 of the heat generation layer 130 generates heat by receiving a power supply, and possible embodiments are not particularly limited, but a nichrome wire or a stainless steel wire may be used.

To prevent electrical leakage, it is desirable to electrically insulate the heating wire 131. For example, it is possible to realize the electrical insulation of the heating wire 131, by covering the heating wire 131 with an inorganic fiber sleeve including inorganic fibers such as glass fibers, silica fibers, alumina fibers, or silica alumina fibers or coating the heating wire 131 with a resin.

In addition to the heat source (the heating wire 131), the heat generation layer 130 may include a supporting member 132. The supporting member 132 is a material for fixing (supporting) the heating wire 131, and it is acceptable to use, for example, an inorganic fiber cloth including inorganic fibers such as glass fibers, silica fibers, alumina fibers, or silica alumina fibers. The fixation of the heating wire 131 to the supporting member 132 may be realized, for example, by sewing the heating wire 131 onto the supporting member 132 by using a sewing thread having heat resistance.

It is sufficient as long as the thermal insulation layer 140 is structured by using a material capable of preventing the heat generated from the heat generation layer 130 from being released to the outside via the outer layer 120, and possible embodiments are not particularly limited, but it is acceptable to use an inorganic fiber mat obtained by, for example, integrating together glass fibers, ceramic fibers, silica fibers, or the like and applying needle processing thereto. In this situation, the inorganic fiber mat may be shaped as a mat, by further adding thereto an inorganic binder such as colloidal silica, alumina sol, or silicic acid or an organic binder such as starch. Further, the thermal insulation layer 140 may be a porous molded product using a heat-resistant organic resin such as aramid, polyamide, or polyimide. The thickness of the material having such thermal insulation characteristics may preferably be in the range of 5 mm to 100 mm, and more preferably in the range of 5 mm to 50 mm, and even more preferably in the range of 8 mm to 30 mm.

Other than the materials presented above, for the thermal insulation layer 140, it is also acceptable to use a fiber body (an aerogel fiber body) filled with aerogel. The aerogel fiber body is a thermal insulation material obtained by filling a fiber base material with aerogel. It is acceptable to use, for example, the aerogel fiber body disclosed in International Publication No. WO 2012/077648.

FIG. 2 is a cross-sectional view taken at A-A′ of the jacket heater 100 shown in FIG. 1. As shown in FIG. 2, the jacket heater 100 according to the present embodiment includes a temperature sensor 150. The temperature sensor 150 includes: a temperature detection point 151 for detecting temperature of a measured object; and a cable part 152 extending from the temperature detection point 151. The temperature of the measured object is detected by the temperature sensor 150 as a result of an electrical signal corresponding to heat detected at the temperature detection point 151 being transferred via the cable part 152. Possible examples of the temperature sensor 150 include a thermocouple and a resistance thermometer.

Of the temperature sensor 150, the temperature detection point 151 and a part of the cable part 152 are fixed while being exposed to the inner surface (the surface being in contact with the pipe P) of the inner layer 110. Of the cable part 152, the part excluding the part exposed to the inner surface of the inner layer 110 penetrates the inner layer 110, the heat generation layer 130, the thermal insulation layer 140, and the outer layer 120, starting with the inner layer 110 toward the outer layer 120, so as to be fixed while a part including an end part is exposed from the outer surface of the outer layer 120. Possible methods for fixing the cable part 152 to the inner surface of the inner layer 110 and the outer surface of the outer layer 120 are not particularly limited. For example, it is acceptable to use a method by which the cable part 152 is sewn onto the inner surface of the inner layer 110 and the outer surface of the outer layer 120 by using a sewing thread Y having heat resistance.

Of the cable part 152, the part penetrating the inner layer 110, the heat generation layer 130, the thermal insulation layer 140, and the outer layer 120 (the part that is not exposed from the inner surface of the inner layer 110 or the outer surface of the outer layer 120) includes: a thermal insulation layer derivation part 152a being a section derived from the thermal insulation layer 140 to the space between the thermal insulation layer 140 and the outer layer 120; and an outer layer introduction part 152b being a section introduced from the space between the thermal insulation layer 140 and the outer layer 120 to the outer layer 120. In the jacket heater 100 according to the present embodiment, the section from the thermal insulation layer derivation part 152a to the outer layer introduction part 152b is positioned, as shown in FIG. 2, on a bypassing path bypassing a linear path connecting the thermal insulation layer derivation part 152a to the outer layer introduction part 152b. In other words, in the jacket heater 100 according to the present embodiment, the certain section of the cable part 152 positioned between the thermal insulation layer 140 and the outer layer 120 is positioned on the bypassing path that bypasses the thermal insulation layer derivation part 152a and the outer layer introduction part 152b.

The bypassing path on which the section from the thermal insulation layer derivation part 152a to the outer layer introduction part 152b (the certain section of the cable part 152 that is positioned between the thermal insulation layer 140 and the outer layer 120) is positioned is, more specifically, a path that extends from the thermal insulation layer derivation part 152a in the direction of an arrow D1, turns and extends in the direction of an arrow D2 perpendicular to the direction of the arrow D1, and further turns and extends in the direction of an arrow D3 perpendicular to the direction of the arrow D2 and parallel to the arrow DI, so as to reach the outer layer introduction part 152b. Because the bypassing path includes the path extending in the directions (i.e., the directions of the arrows D1 to D3) forming prescribed angles with respect to a linear direction (a D direction) connecting the thermal insulation layer derivation part 152a to the outer layer introduction part 152b, the bypassing path is the path bypassing the linear path connecting the thermal insulation layer derivation part 152a to the outer layer introduction part 152b. In this situation, it is sufficient as long as the bypassing path is a path bypassing the linear path connecting the thermal insulation layer derivation part 152a to the outer layer introduction part 152b. Possible embodiments are not limited to the bypassing path shown in FIG. 2.

The section from the thermal insulation layer derivation part 152a to the outer layer introduction part 152b that is positioned on the bypassing path may be fixed to the thermal insulation layer 140 (the outer surface of the thermal insulation layer 140 (the surface being in contact with the outer layer 120) ) or to the outer layer 120 (the inner surface of the outer layer 120 (the surface being in contact with the thermal insulation layer 140)). Possible methods of the fixation to the thermal insulation layer 140 or to the outer layer 120 are not particularly limited. For example, it is acceptable to use a method by which the section from the thermal insulation layer derivation part 152a to the outer layer introduction part 152b is sewn onto the thermal insulation layer 140 and the outer layer 120, by using a sewing thread having heat resistance. In this situation, the cable part 152 may directly be sewn onto the layer to be sewn onto. Alternatively, to make it easier to fix the cable part 152, an inorganic fiber cloth such as a glass fiber cloth may be applied to a surface of the layer to be sewn onto, so that the cable part 152 is sewn via the cloth. In another example, the cable part 152 that has been sewn onto the layer may be covered by an inorganic fiber cloth, so that the inorganic fiber cloth is further sewn onto the layer onto which the cable part 152 has been sewn.

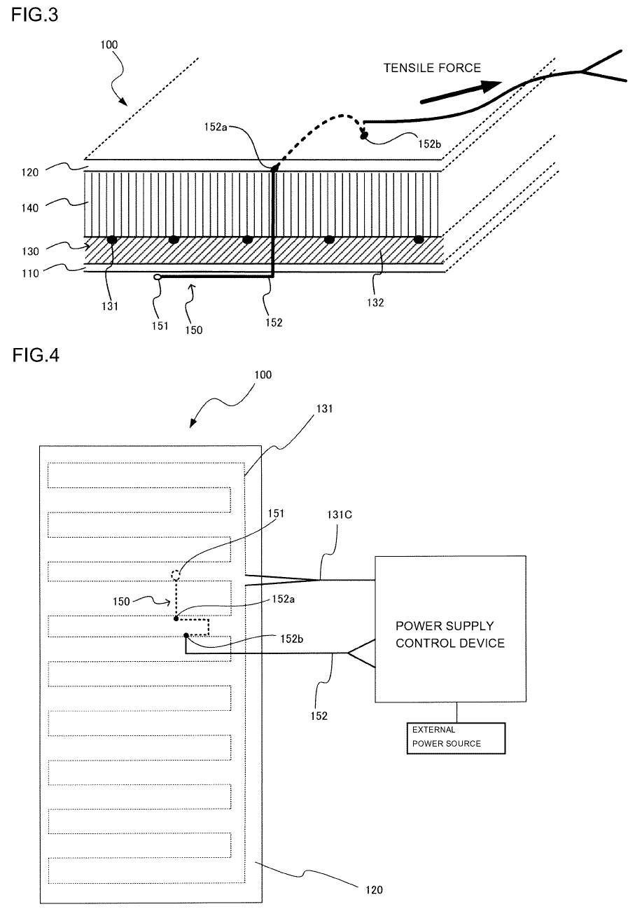

In the jacket heater 100 according to the present embodiment, because the certain section of the cable part 152 from the thermal insulation layer derivation part 152a to the outer layer introduction part 152b (the section of the cable part 152 positioned between the thermal insulation layer 140 and the outer layer 120) is positioned on the bypassing path bypassing the linear path connecting the thermal insulation layer derivation part 152a to the outer layer introduction part 152b, there is a slack between the thermal insulation layer derivation part 152a and the outer layer introduction part 152b. For this reason, even when tensile force is applied to the cable part 152 exposed from the outer surface of the outer layer 120, no excessive tensile force will be applied to the cable part 152 until the slack between the thermal insulation layer derivation part 152a and the outer layer introduction part 152b is cancelled (until the section from the thermal insulation layer derivation part 152a to the outer layer introduction part 152b turns out to be positioned on the linear path connecting the thermal insulation layer derivation part 152a to the outer layer introduction part 152b), although the length of the cable part 152 exposed from the outer surface of the outer layer 120 becomes longer, as shown in FIG. 3. Consequently, the jacket heater 100 according to the present embodiment is configured so that a wiring disconnection does not easily occur in the cable part 152, even when tensile force is applied to the cable part 152. In the present disclosure, the wiring disconnection in the cable part 152 is a concept that includes not only the wiring disconnection of the cable part 152 itself, but also a wiring disconnection of an element wire (a lead wire) accommodated inside the cable part 152.

Further, as shown in FIG. 3, even when tensile force is applied to the cable part 152 exposed from the outer surface of the outer layer 120, and the length of the cable part 152 exposed from the outer surface of the outer layer 120 becomes longer, the position of the thermal insulation layer derivation part 152a in the cable part 152 hardly changes until the slack between the thermal insulation layer derivation part 152a and the outer layer introduction part 152b is cancelled, although the position of the outer layer introduction part 152b in the cable part 152 changes. Consequently, in the jacket heater 100 according to the present embodiment, because such tensile force is not easily transmitted to the section of the cable part 152 extending from the thermal insulation layer derivation part 152a to reach the temperature detection point 151, the position of the temperature detection point 151 is not easily displaced.

As explained above, in the jacket heater 100 according to the present embodiment, because the cable part 152 has the slack in the section from the thermal insulation layer derivation part 152a to the outer layer introduction part 152b positioned on the bypassing path, even when tensile force is applied to the cable part 152 exposed from the outer surface of the outer layer 120, the section from the thermal insulation layer derivation part 152a to the outer layer introduction part 152b forming the slack acts as a buffer part. Consequently, a wiring disconnection does not easily occur in the cable part 152, and the position of the temperature detection point 151 is not easily displaced.

Next, a method for using the jacket heater 100 according to the present embodiment will be explained, with reference to FIG. 4. FIG. 4 is an unfolded view of the jacket heater 100, as seen from the outer layer 120 side. As shown in FIG. 4, the jacket heater 100 according to the present embodiment may be used while being connected to a power supply control device connected to an external power source. More specifically, the jacket heater 100 may be used while being connected to the power supply control device via the heating wire cable 131C connected to the heating wire 131 and the cable part 152 of the temperature sensor 150.

The power supply control device supplies the power to the heating wire 131 via the heating wire cable 131C. As a result of the power being supplied to the heating wire 131, the heating wire 131 generates the heat. Further, the power supply control device receives thermal electromotive force based on heat (a temperature difference) transferred via the cable part 152 of the temperature sensor 150 and judges whether or not the temperature of the measured object (the pipe P) calculated from the thermal electromotive force is within a prescribed range. When it is determined that the temperature of the measured object is within the prescribed range, the power supply control device exercises power supply control on the heating wire 131 so that the temperature of the heated object is maintained at that temperature. On the contrary, when it is determined that the temperature of the measured object (the pipe P) is higher than the prescribed range, the power supply control device exercises power supply control on the heating wire 131 so that the temperature of the heated object (the pipe P) becomes lower than the present temperature. When it is determined that the temperature of the measured object (the pipe P) is lower than the prescribed range, the power supply control device exercises power supply control on the heating wire 131 so that the temperature of the heated object (the pipe P) becomes higher than the present temperature.

By using the jacket heater 100 according to the present embodiment while being connected to the power supply control device described above, it is possible to adjust the temperature of the heated object while detecting the temperature of the heated object. Consequently, it is possible to maintain the heated object within the desired temperature range. In this situation, the power supply control exercised by the power supply control device is not limited to the power supply control described above. It is acceptable to use any power supply control schemes hitherto known publicly.

In the jacket heater 100 according to the present embodiment, in addition to the cable part 152 of the temperature sensor 150, the heating wire cable 131C connected to the heating wire 131 may be positioned on the bypassing path. In other words, the heating wire cable 131C connected to the heating wire 131 may penetrate the thermal insulation layer 140 and the outer layer 120 starting with the heat generation layer 130 toward the outer layer 120, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer 130, the thermal insulation layer 140, and the outer layer 120. In that situation, because the certain section of the heating wire cable 131C from the derivation part to the introduction part is positioned on the bypassing path bypassing the linear path connecting the derivation part to the introduction part, there is a slack in the section between the derivation part and the introduction part. Accordingly, a wiring disconnection does not easily occur in the heating wire cable 131C, and the position of the heating wire 131 is not easily displaced. In addition, the cable part 152 of the temperature sensor 150 may extend through the through holes which are formed in the thermal insulation layer 140 and the outer layer 120 and through which the heating wire cable 131C of the heating wire 131 passes, but may extend through other through holes (through holes formed in the thermal insulation layer 140 and the outer layer 120) that are different from the through hole through which the heating wire cable 131C of the heating wire 131 passes.

It is possible to manufacture the jacket heater 100 according to the present embodiment by implementing a method including: a step of forming a laminated body including the inner layer 110, the outer layer 120, as well as the heat generation layer 130 and the thermal insulation layer 140 provided between the inner layer 110 and the outer layer 120, the laminated body having fixed thereto the temperature sensor 150 including the temperature detection point 151 and the cable part 152 extending from the temperature detection point 151. In the step of forming the laminated body, the temperature detection point 151 is positioned on the inner surface of the inner layer 110. Further, in the step of forming the laminated body, the cable part 152 penetrates the inner layer 110, the heat generation layer 130, the thermal insulation layer 140, and the outer layer 120, starting with the inner layer 110 toward the outer layer 120, while the section from the derivation part derived from one of the adjacently-positioned layers to the introduction part introduced to the other layer of the adjacently-positioned layers is positioned on the path bypassing the linear path connecting the derivation part to the introduction part, in a space between the adjacently-positioned layers including at least one of the inner layer 110, the heat generation layer 130, the thermal insulation layer 140, and the outer layer 120.

Next, modification examples of the jacket heater 100 according to the present embodiment will be explained. In the following modification examples, some of the constituent elements that are the same as those of the jacket heater 100 in the present embodiment will be referred to by using the same reference characters, and detailed explanations thereof will be omitted.

### [First Modification Example of First Embodiment]

In the jacket heater 100 according to the present embodiment shown in FIGS. 1 to 4, the thermal insulation layer derivation part 152a and the outer layer introduction part 152b of the cable part 152 are provided in the positions that do not overlap each other in the lamination direction of the inner layer 110, the heat generation layer 130, the thermal insulation layer 140, and the outer layer 120 (see FIGS. 2 to 4, in particular). In a jacket heater according to the present first modification example, as shown in FIG. 5, the thermal insulation layer derivation part 152a and the outer layer introduction part 152b are provided in positions that overlap with each other in the lamination direction. Even when the jacket heater 100 is structured in this manner, there is a slack between the thermal insulation layer derivation part 152a and the outer layer introduction part 152b, as long as the section from the thermal insulation layer derivation part 152a to the outer layer introduction part 152b (the certain section of the cable part 152 positioned between the thermal insulation layer 140 and the outer layer 120) is positioned on the bypassing path bypassing the linear path connecting the thermal insulation layer derivation part 152a to the outer layer introduction part 152b. Accordingly, because the section from the thermal insulation layer derivation part 152a to the outer layer introduction part 152b acts as a buffer part, the jacket heater 100 according to the present first modification example is also structured so that a wiring disconnection does not easily occur in the cable part 152, and the position of the temperature detection point 151 is not easily displaced.

### [Second Modification Example of First Embodiment]

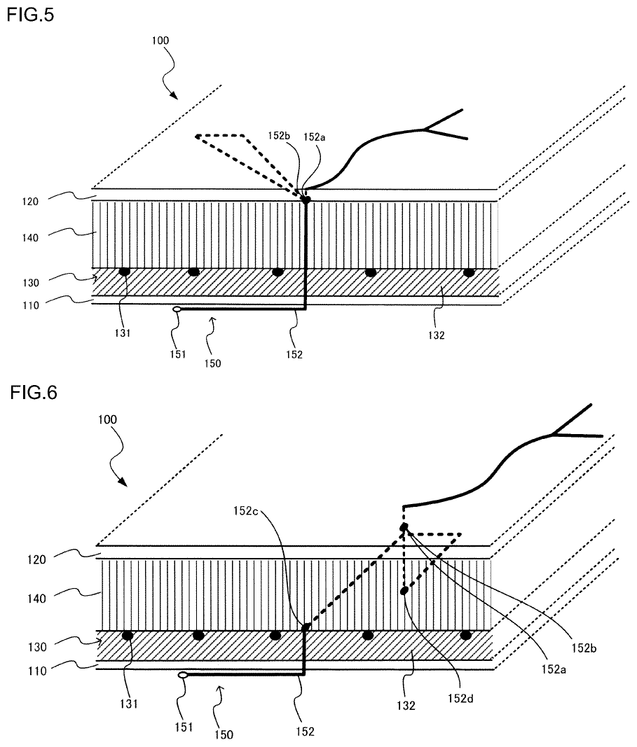

In the jacket heater 100 according to the present embodiment shown in FIGS. 1 to 4, the section of the cable part 152 from the thermal insulation layer derivation part 152a to the outer layer introduction part 152b (the certain section of the cable part 152 positioned between the thermal insulation layer 140 and the outer layer 120) is positioned on the bypassing path bypassing the linear path connecting the thermal insulation layer derivation part 152a to the outer layer introduction part 152b, in the inter-layer space between the thermal insulation layer 140 and the outer layer 120. In contrast, in the jacket heater 100 according to the present second modification example, as shown in FIG. 6, the section from a heat generation layer derivation part 152c to a thermal insulation layer introduction part 152d is positioned on a bypassing path bypassing a linear path connecting the heat generation layer derivation part 152c to the thermal insulation layer introduction part 152d, in the inter-layer space between the heat generation layer 130 and the thermal insulation layer 140. In other words, in the jacket heater 100 according to the present second modification example, the certain section of the cable part 152 positioned between the heat generation layer 130 and the thermal insulation layer 140 is positioned on the bypassing path bypassing the linear path connecting the heat generation layer derivation part 152c to the thermal insulation layer introduction part 152d. In this situation, the heat generation layer derivation part 152c is a section derived from the heat generation layer 130 to the space between the heat generation layer 130 and the thermal insulation layer 140. The thermal insulation layer introduction part 152d is a section introduced from the space between the heat generation layer 130 and the thermal insulation layer 140 to the thermal insulation layer 140.

Even when the jacket heater 100 according to the present second modification example is structured in this manner, because the section of the cable part 152 from the heat generation layer derivation part 152c to the thermal insulation layer introduction part 152d (the section positioned between the heat generation layer 130 and the thermal insulation layer 140) is positioned on the bypassing path bypassing the linear path connecting the heat generation layer derivation part 152c to the thermal insulation layer introduction part 152d, there is a slack in the section between the heat generation layer derivation part 152c and the thermal insulation layer introduction part 152d. For this reason, because the section from the heat generation layer derivation part 152c to the thermal insulation layer introduction part 152d acts as a buffer part, the jacket heater 100 according to the present second modification example is also structured so that a wiring disconnection does not easily occur in the cable part 152, and the position of the temperature detection point 151 is not easily displaced.

### [Third Modification Example of First Embodiment]

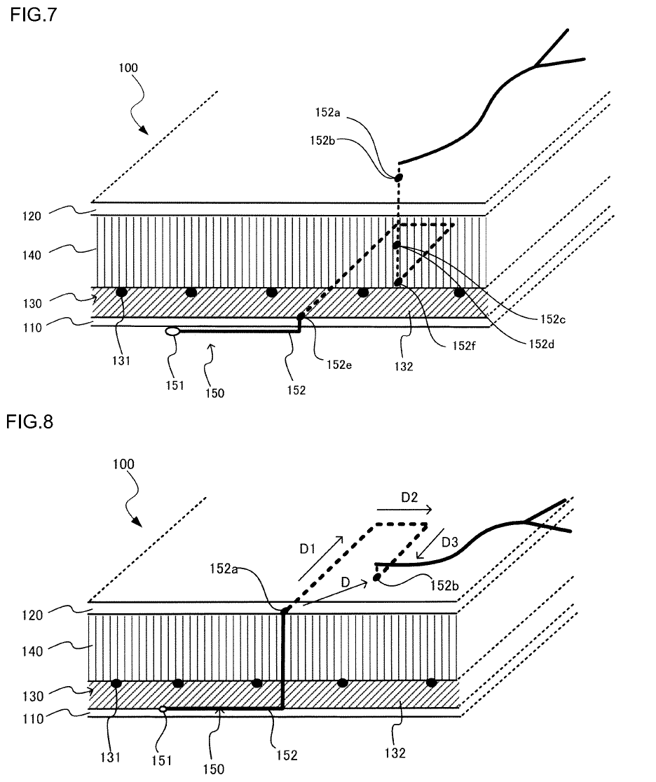

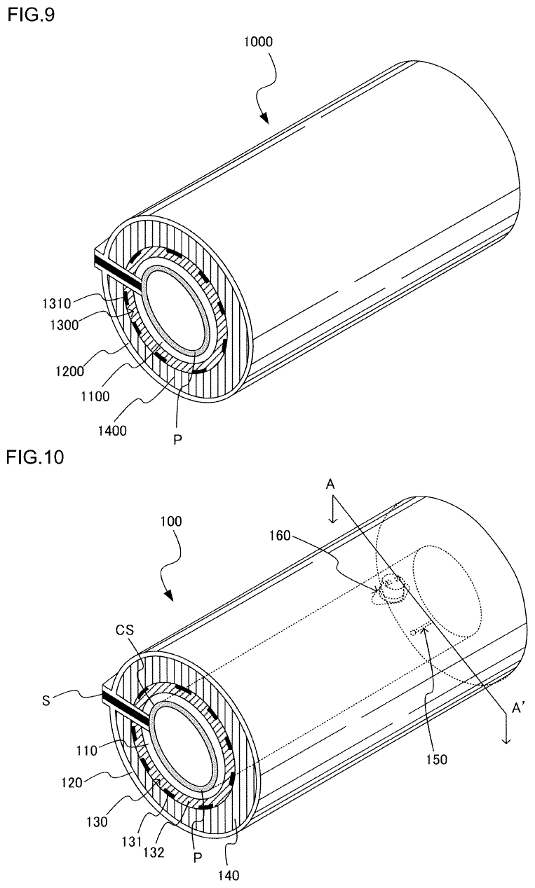

In the jacket heater 100 according to the present embodiment shown in FIGS. 1 to 4, the section of the cable part 152 from the thermal insulation layer derivation part 152a to the outer layer introduction part 152b (the certain section of the cable part 152 positioned between the thermal insulation layer 140 and the outer layer 120) is positioned on the bypassing path bypassing the linear path connecting the thermal insulation layer derivation part 152a to the outer layer introduction part 152b, in the inter-layer space between the thermal insulation layer 140 and the outer layer 120. In contrast, in the jacket heater 100 according to the present third modification example, as shown in FIG. 7, the section from an inner layer derivation part 152e to a heat generation layer introduction part 152f is positioned on a bypassing path bypassing a linear path connecting the inner layer derivation part 152e to the heat generation layer introduction part 152f, in the inter-layer space between the inner layer 110 and the heat generation layer 130. In other words, in the jacket heater 100 according to the present third modification example, the certain section of the cable part 152 positioned between the inner layer 110 and the heat generation layer 130 is positioned on the bypassing path bypassing the linear path connecting the inner layer derivation part 152e to the heat generation layer introduction part 152f. In this situation, the inner layer derivation part 152e is a section derived from the inner layer 110 to the space between the inner layer 110 and the heat generation layer 130. The heat generation layer introduction part 152f is a section introduced from the space between the inner layer 110 and the heat generation layer 130 to the heat generation layer 130.

Even when the jacket heater 100 according to the present third modification example is structured in this manner, because the section of the cable part 152 from the inner layer derivation part 152e to the heat generation layer introduction part 152f (the section positioned between the inner layer 110 and the heat generation layer 130) is positioned on the bypassing path bypassing the linear path connecting the inner layer derivation part 152e to the heat generation layer introduction part 152f, there is a slack between the inner layer derivation part 152e and the heat generation layer introduction part 152f. Accordingly, because the section from the inner layer derivation part 152e to the heat generation layer introduction part 152f acts as a buffer part, the jacket heater 100 according to the present third modification example is also structured so that a wiring disconnection does not easily occur in the cable part 152, and the position of the temperature detection point 151 is not easily displaced.

### [Fourth Modification Example of First Embodiment]

In the jacket heater 100 shown in FIGS. 1 to 7, of the cable part 152, one of the following sections is positioned on the bypassing path: the section from the thermal insulation layer derivation part 152a to the outer layer introduction part 152b (the section positioned between the thermal insulation layer 140 and the outer layer 120) ; the section from the heat generation layer derivation part 152c to the thermal insulation layer introduction part 152d (the section positioned between the heat generation layer 130 and the thermal insulation layer 140); and the section from the inner layer derivation part 152e to the heat generation layer introduction part 152f (the section positioned between the inner layer 110 and the heat generation layer 130). In contrast, in the jacket heater 100 according to the present fourth modification example, two or more selected from among these sections are positioned on a bypassing path (not shown).

As explained above, the section of the cable part 152 positioned on the bypassing path serves as a slack. Thus, there is a slack even when the two or more sections are positioned on the bypassing pass. Because the slack acts as a buffer part, even when the jacket heater 100 according to the present fourth modification example is structured so that two or more sections selected from among the following are positioned on the bypassing path, a wiring disconnection does not easily occur in the cable part 152, and the position of the temperature detection point 151 is not easily displaced: the section from the thermal insulation layer derivation part 152a to the outer layer introduction part 152b (the section positioned between the thermal insulation layer 140 and the outer layer 120); the section from the heat generation layer derivation part 152c to the thermal insulation layer introduction part 152d (the section positioned between the heat generation layer 130 and the thermal insulation layer 140); and the section from the inner layer derivation part 152e to the heat generation layer introduction part 152f (the section positioned between the inner layer 110 and the heat generation layer 130).

### [Fifth Modification Example of First Embodiment]

In the jacket heater 100 shown in FIGS. 1 to 7, the thermal insulation layer 140 is structured as a single layer. In contrast, in the jacket heater 100 according to the present fifth modification example, the thermal insulation layer 140 is structured with two layers. More specifically, in the jacket heater 100 according to the present fifth modification example, the thermal insulation layer 140 is structured with the two layers (not shown) such as a first thermal insulation layer provided between the heat generation layer 130 and the outer layer 120 and a second thermal insulation layer provided between the first thermal insulation layer and the outer layer 120. Further, in the inter-layer space between the first thermal insulation layer and the second thermal insulation layer, a certain section of the cable part 152 from a first thermal insulation layer derivation part to a second thermal insulation layer introduction part is positioned on a bypassing path bypassing a linear path connecting the first thermal insulation layer derivation part to the second thermal insulation layer introduction part (not shown). In other words, in the jacket heater 100 according to the present fifth modification example, the certain section of the cable part 152 positioned between the first thermal insulation layer and the second thermal insulation layer is positioned on the bypassing path bypassing the linear path connecting the first thermal insulation layer derivation part to the second thermal insulation layer introduction part. In this situation, the first thermal insulation layer derivation part is a section derived from the first thermal insulation layer to the space between the first thermal insulation layer and the second thermal insulation layer. The second thermal insulation layer introduction part is a section introduced from the space between the first thermal insulation layer and the second thermal insulation layer to the second thermal insulation layer.

Even when the jacket heater 100 according to the present fifth modification example is structured in this manner, because the section of the cable part 152 from the first thermal insulation layer derivation part to the second thermal insulation layer introduction part (the section positioned between the first thermal insulation layer and the second thermal insulation layer) is positioned on the bypassing path bypassing the linear path connecting the first thermal insulation layer derivation part to the second thermal insulation layer introduction part, there is a slack between the first thermal insulation layer derivation part and the second thermal insulation layer introduction part. Accordingly, because the section from the first thermal insulation layer derivation part to the second thermal insulation layer introduction part acts as a buffer part, the jacket heater 100 according to the present fifth modification example is also structured so that a wiring disconnection does not easily occur in the cable part 152, and the position of the temperature detection point 151 is not easily displaced. In this situation, although the part of the cable part 152 positioned on the bypassing path is positioned between the first thermal insulation layer and the second thermal insulation layer in the present fifth modification example, the part of the cable part 152 may be positioned between the second thermal insulation layer and the outer layer 120, between the first thermal insulation layer and the heat generation layer 130, or between the inner layer 110 and the heat generation layer 130.

### [Sixth Modification Example of First Embodiment]

In the jacket heater 100 shown in FIGS. 1 to 7, the temperature detection point 151 of the temperature sensor 150 is exposed to the inner surface of the inner layer 110. In contrast, in the jacket heater 100 according to the present sixth modification example, as shown in FIG. 8, the temperature detection point 151 of the temperature sensor 150 is positioned between the inner layer 110 and the heat generation layer 130. Further, a certain part of the cable part 152 extending from the temperature detection point 151 is fixed in the space between the inner layer 110 and the heat generation layer 130, while the part other than the part fixed in the space between the inner layer 110 and the heat generation layer 130 penetrates the heat generation layer 130, the thermal insulation layer 140, and the outer layer 120 starting with the space between the inner layer 110 and the heat generation layer 130 toward the outer layer 120, so as to be fixed while a part thereof including an end part is exposed from the outer surface of the outer layer 120.

Even when the jacket heater 100 according to the present sixth modification example is structured in this manner, there is a slack because the section from the thermal insulation layer derivation part 152a to the outer layer introduction part 152b (the section positioned between the thermal insulation layer 140 and the outer layer 120) is positioned on the bypassing path bypassing the linear path connecting the thermal insulation layer derivation part 152a to the outer layer introduction part 152b. Accordingly, because the section from the thermal insulation layer derivation part 152a to the outer layer introduction part 152b acts as a buffer part, in the jacket heater 100 according to the present sixth modification example also, a wiring disconnection does not easily occur in the cable part 152, and the position of the temperature detection point 151 is not easily displaced. Further, although the part of the cable part 152 positioned on the bypassing path is positioned between the thermal insulation layer 140 and the outer layer 120 in the present sixth modification example shown in FIG. 8, the part of the cable part 152 may be positioned between the thermal insulation layer 140 and the heat generation layer 130. Furthermore, when the thermal insulation layer 140 is structured with two layers such as the first thermal insulation layer and the second thermal insulation layer like in the fifth modification example, the part of the cable part 152 positioned on the bypassing path may be positioned between the first thermal insulation layer and the second thermal insulation layer.

It is possible to manufacture the jacket heater 100 according to the present sixth modification example by implementing a method including: a step of forming a laminated body including the inner layer 110, the outer layer 120, as well as the heat generation layer 130 and the thermal insulation layer 140 provided between the inner layer 110 and the outer layer 120, the laminated body having fixed thereto the temperature sensor 150 including the temperature detection point 151 and the cable part 152 extending from the temperature detection point 151. In the step of forming the laminated body, the temperature detection point 151 is positioned between the inner layer 110 and the heat generation layer 130. Further, in the step of forming the laminated body, the cable part 152 penetrates the heat generation layer 130, the thermal insulation layer 140, and the outer layer 120, starting with the space between the inner layer 110 and the heat generation layer 130 toward the outer layer 120, while the section from the derivation part derived from the one of the adjacently-positioned layers to the introduction part introduced to the other layer of the adjacently-positioned layers is positioned on the path bypassing the linear path connecting the derivation part to the introduction part, in a space between adjacently-positioned layers including at least one of the heat generation layer 130, the thermal insulation layer 140, and the outer layer 120.

### Second Embodiment

Next, a jacket heater according to a second embodiment of the present invention will be explained.

Similarly to the jacket heater 100 according to the first embodiment, in the jacket heater 100 according to the present embodiment, a partial section of the cable part 152 of the temperature sensor 150 is positioned on the aforementioned bypassing path. In addition, the present embodiment is characterized in that a temperature detection point of the temperature sensor 150 is provided in a position that does not overlap with the heating wire 131, in a direction perpendicular to a contact surface CS between the heated object (the pipe P) and the inner layer 110.

Next, the jacket heater 100 according to the present embodiment will be explained, with reference to FIGS. 10 to 15. In this situation, some of the constituent elements that were explained for the jacket heater 100 according to the first embodiment will be referred to by using the same reference characters, and detailed explanations thereof will be omitted.

As shown in FIG. 10, the jacket heater 100 according to the present embodiment includes a thermostat 160, in addition to the temperature sensor 150, as a sensor for detecting temperature. However, it is sufficient as long as the jacket heater 100 according to the present embodiment includes the temperature sensor 150, and the thermostat 160 does not necessarily need to be included. Further, in place of the thermostat 160, a thermistor or a temperature fuse by which a temperature is obtained from a resistance value may be used.

The temperature sensor 150 includes the temperature detection point 151 for detecting temperature of a measured object and the cable part 152 extending from the temperature detection point 151 and may be realized by using one of a thermocouple and a resistance thermometer, for example. A specific example of the thermocouple (the temperature sensor 150) may be the thermocouple shown in FIG. 11, for instance. The thermocouple shown in FIG. 11 includes: a positive-side thermocouple element wire A formed by using a metal; a negative-side thermocouple element wire B formed by using a different type of metal from that of the positive-side thermocouple element wire A; an inorganic electrical insulator D using magnesia (MgO) or the like for electrically insulating the positive-side thermocouple element wire A and the negative-side thermocouple element wire B; and a sheath C for accommodating these elements therein. In the thermocouple shown in FIG. 11, the temperature detection point 151 corresponds to a tip end part of the thermocouple in which a contact point I between the positive-side thermocouple element wire A and the negative-side thermocouple element wire B is present. The cable part 152 is a part excluding the tip end part of the thermocouple. In the thermocouple shown in FIG. 11, electromotive force corresponding to a temperature difference between the positive-side thermocouple element wire A and the negative-side thermocouple element wire B occurs, and it is thus possible to detect the temperature of the measured object.

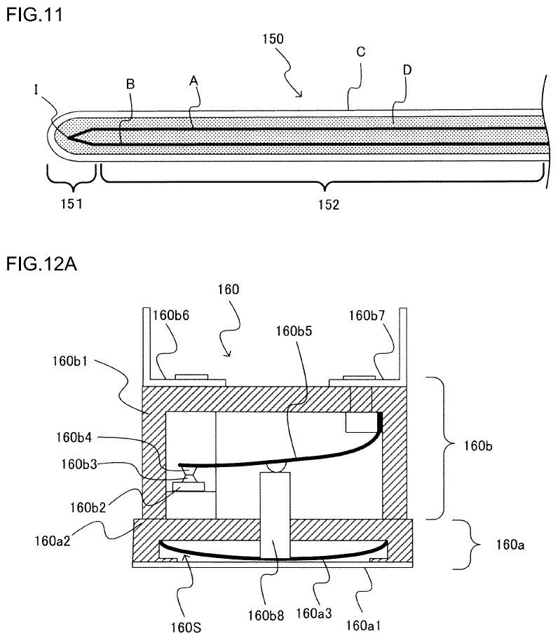

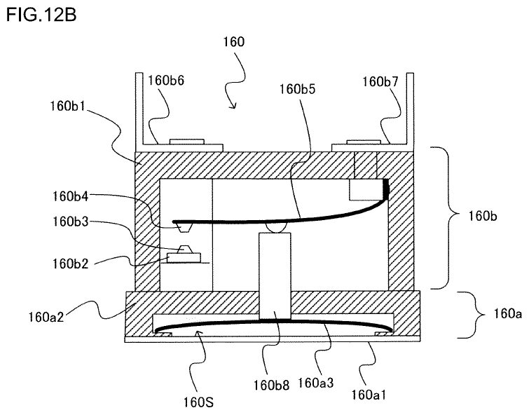

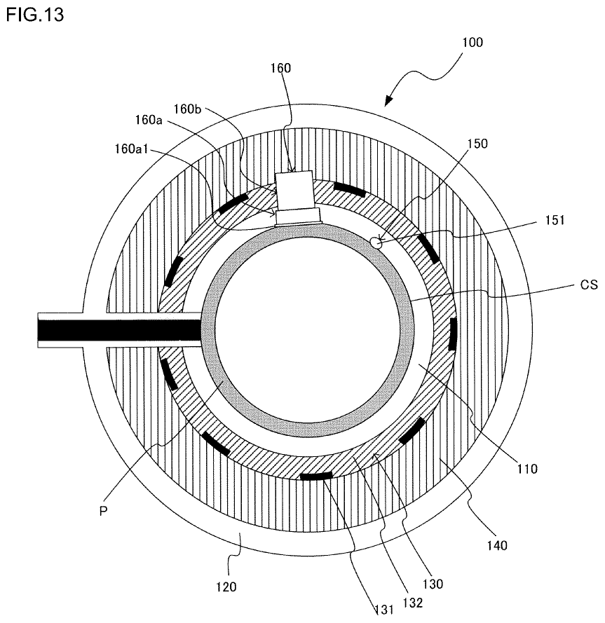

The thermostat 160 is a temperature sensor that goes into operation (yields an output) when the temperature of the measured object has reached a prescribed level and includes, for example, as shown in FIG. 12A, a temperature detection unit 160a (i.e., a temperature detection point) that detects the temperature of the measured object and goes into operation when the detected temperature has reached the prescribed level; and a contraption part 160b that blocks an electrical connection according to the operation from the temperature detection unit 160a. The temperature detection unit 160a includes: a metal cap 160a1 being in contact with the measured object; a retainer 160a2 forming a space 160S with the metal cap 160a1; and a bimetal 160a3 that is installed in the space 160S and has a spherical shape obtained by pasting together two metal sheets having mutually-different thermal expansion coefficients. The contraption part 160b includes: a case 160b1; a fixed plate 160b2 having an electrical contact point 160b3 provided inside the case 160b1; a movable plate 160b5 having an electrical contact point 160b4 opposing the electrical contact point 160b3; a pin 160b8 fixed to the movable plate 160b5 and the bimetal 160a3; a terminal 160b6 that is provided outside the case 160b1 and is electrically conductive with the fixed plate 160b2; and a terminal 160b7 that is provided outside the case 160b1 and is electrically conductive with the movable plate 160b5. In this situation, to the terminal 160b6 and the terminal 160b7, a thermostat cable 160C (explained later) is connected.

When the temperature of the measured object being in contact with the metal cap 160a1 has risen and reached the prescribed level, the bimetal 160a3 makes a reversal movement as shown in FIG. 12B due to the temperature change. Accordingly, the pin 160b8 transmits the deformation of the bimetal 160a3 to the movable plate 160b5. As a result, the electrical contact point 160b3 and the electrical contact point 160b4 operate to make an opening movement. Because the opening movement made by the electrical contact points 160b3 and 160b4 blocks the electrical connection between the electrical contact point 160b3 and the electrical contact point 160b4, it is possible to determine that the temperature of the measured object has reached the prescribed level, by detecting the blockage of the electrical connection. In this situation, the bimetal 160a3 that reversed itself as shown in FIG. 12B returns to the state shown in FIG. 12A, when the temperature of the measured object is cooled so as to be lower than the prescribed level. As a result, the electrical connection between the electrical contact point 160b3 and the electrical contact point 160b4 is restored. By detecting the restoration of the electrical connection, it is possible to determine that the temperature of the measured object has become lower than the prescribed level.

In relation to the above, possible configurations of the thermostat 160 are not limited to those shown in FIGS. 12A and 12B, and it is possible to adopt any configuration hitherto known publicly. Further, the thermostat 160 is not limited to the abovementioned automatic restoration type where the electrical connection is automatically restored when the temperature has become lower than a second prescribed temperature that is lower than the prescribed level at which the electrical connection is blocked. It is also acceptable to use a manual restoration type where the blocked electrical connection is manually restored or a one-shot type characterized in that the second prescribed temperature being lower than the prescribed temperature at which the electrical connection is blocked is lower than a room temperature.

FIG. 13 is a cross-sectional view taken at A-A′ of the jacket heater 100 shown in FIG. 10. As shown in FIG. 13, in the jacket heater 100 according to the present embodiment, of the temperature sensor 150, the temperature detection point 151 and a certain part of the cable part 152 connected to the temperature detection point 151 are fixed while being exposed to the inner surface (the surface being in contact with the pipe P) of the inner layer 110. Because the temperature detection point 151 is exposed to the inner surface of the inner layer 110, the temperature sensor 150 is able to detect the temperature (identify the temperature) of the pipe P.

In this situation, of the cable part 152, the part excluding the part exposed to the inner surface of the inner layer 110 penetrates the inner layer 110, the heat generation layer 130, the thermal insulation layer 140, and the outer layer 120, starting with the inner layer 110 toward the outer layer 120, so as to be fixed while a part thereof including an end part is exposed from the outer surface of the outer layer 120 (not shown). In this situation, the cable part 152 is positioned on the bypassing path described above, in an intermediate part within the penetration from the inner layer 110 to the outer layer 120.

As shown in FIG. 13, the thermostat 160 penetrates the inner layer 110, the heat generation layer 130, and a part of the thermal insulation layer 140 and is fixed to a position enclosed by these three layers. The metal cap 160a1 of the temperature detection unit 160a serving as the temperature detection point is exposed from the surface (the inner surface) of the inner layer 110 and is thus able to come into contact with the pipe P. Because the metal cap 160a1 is exposed from the surface (the inner surface) of the inner layer 110, the thermostat 160 is able to detect the temperature of the pipe P (to determine whether or not the prescribed temperature has been reached). Possible methods for fixing the thermostat 160 onto the inner layer 110, the heat generation layer 130, and the thermal insulation layer 140 are not particularly limited. Similarly to the temperature sensor 150, it is acceptable to use a method, for example, by which the thermostat 160 is sewn onto the inner layer 110, the heat generation layer 130, and the thermal insulation layer 140 by using a sewing thread having heat resistance.

The thermostat 160 (the terminal 160b6 and the terminal 160b7) may be used while being connected to the thermostat cable 160C (explained later; not shown in FIG. 13). The thermostat cable 1600 connected to the thermostat 160 penetrates, for example, a part of the thermal insulation layer 140 and the outer layer 120, so that a part thereof including an end part is exposed from the outer surface of the outer layer 120.

Further, in the jacket heater 100 shown in FIG. 13, the temperature sensor 150 and the thermostat 160 are configured to be able to detect the temperature of the pipe P; however, another configuration is also acceptable in which the temperature inside the jacket heater 100 is detected. For example, the temperature detection point 151 of the temperature sensor 150 may be fixed so as to be positioned between the inner layer 110 and the heat generation layer 130, so that it is possible to measure and detect temperature of the inner layer 110 with which the temperature detection point 151 of the temperature sensor 150 is in contact. When the temperature detection point 151 of the temperature sensor 150 is positioned between the inner layer 110 and the heat generation layer 130, the cable part 152 of the temperature sensor 150 may be structured so that a partial section extending from the temperature detection point 151 is positioned between the inner layer 110 and the heat generation layer 130, while the part excluding the partial section penetrates the heat generation layer 130, the thermal insulation layer 140, and the outer layer 120, starting with the space between the inner layer 110 and the heat generation layer 130 toward the outer layer 120, so that a part including an end part is exposed from the outer surface of the outer layer 120. In another example, the thermostat 160 may be fixed to a position enclosed by two layers, namely, the heat generation layer 130 and the thermal insulation layer 140 in such a manner that the metal cap 160a1 of the thermostat 160 is exposed from the inner surface (the surface being in contact with the inner layer 110) of the heat generation layer 130, so that it is possible to detect temperature of the inner layer 110 with which the metal cap 160a1 is in contact.

In the jacket heater 100 according to the present embodiment, the temperature detection points (the temperature detection point 151 and the temperature detection unit 160a) of the temperature sensor 150 and the thermostat 160 are provided, as shown in FIG. 13, in the positions that do not overlap with the heating wire 131, in a direction perpendicular to the contact surface CS between the pipe P serving as the heated object and the inner layer 110. The direction perpendicular to the contact surface CS between the pipe P and the inner layer 110 is, in other words, the lamination direction of the inner layer 110, the heat generation layer 130, the thermal insulation layer 140, and the outer layer 120. The temperature detection points (i.e., the temperature detection point 151 and the temperature detection unit 160a) of the temperature sensor 150 and the thermostat 160 are provided in the positions that do not overlap with the heating wire 131 in the lamination direction. In this situation, the state in which the temperature detection points do not overlap with the heating wire 131 denotes the state in which no section of the temperature detection points overlaps with the heating wire 131.

Further, when the contact surface CS between the pipe P and the inner layer 110 forms a curved plane as shown in FIG. 13, the direction perpendicular to the contact surface CS is, more specifically, the direction of the normal line of the contact surface CS (the direction perpendicular to a tangent line in contact with the contact surface CS), which also corresponds to the radial direction of the pipe P having a tubular shape.

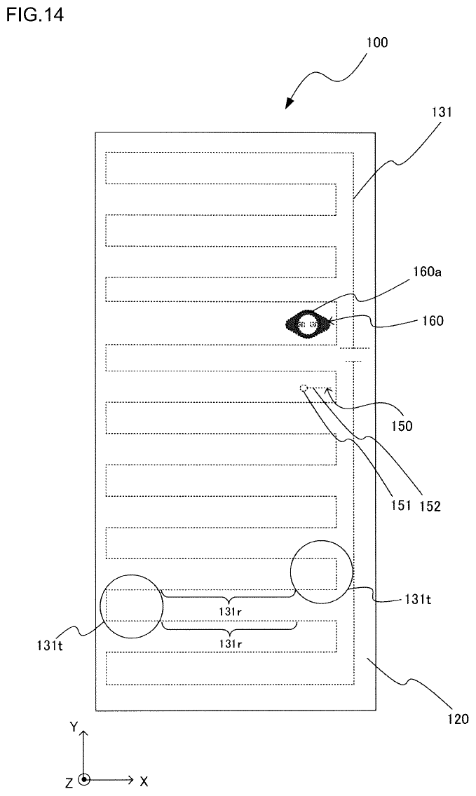

A positional relationship between the temperature detection points of the temperature sensor 150 and the thermostat 160 and the heating wire 131 will be explained more specifically with reference to FIG. 14. FIG. 14 is an unfolded view of the jacket heater 100 as seen from the outer layer 120 side. As for the temperature sensor 150 in FIG. 14, a section thereof exposed to the inner surface of the inner layer 110 is indicated with the broken line. In FIG. 14, the X-Y plane is a plane parallel to the contact surface CS, while the Z-axis corresponds to the direction perpendicular to the contact surface CS.

As shown in FIG. 14, the heating wire 131 extends while being folded back and forth within the heat generation layer 130 (on the X-Y plane) so as to form rows in a prescribed direction (the Y-axis direction in FIG. 14), for the purpose of being able to uniformly heat the pipe P. The heating wire 131 extending in this manner is structured so that one end part of a folded part 131t of a substantially U-shaped structure is connected to one end part of a linear part 131r extending linearly, while the other end part of the linear part 131r is connected to the other end part of another folded part 131t, and this structure is repeated. In other words, the heating wire 131 is structured so that a plurality of folded parts 131t arranged in a staggered manner are connected together via a plurality of linear parts 131r forming rows parallel to one another. In a planar view from the Z-axis direction, the temperature sensor 150 and the thermostat 160 are arranged so as to be positioned between the rows of the heating wire 131. More specifically, in the planar view from the Z-axis direction, the temperature sensor 150 and the thermostat 160 are arranged so as to be surrounded by the folded parts 131t. As a result, the temperature detection point 151 of the temperature sensor 150 and the temperature detection unit 160a serving as a temperature detection point of the thermostat 160 (the section indicated with solid black in FIG. 14) are positioned so as not to overlap with the heating wire 131 in the Z-axis direction.

In this situation, because the thermostat 160 penetrates the heat generation layer 130 provided with the heating wire 131, possible arrangements include being interposed between the linear parts 131r of the heating wire 131 and being surrounded by the folded parts 131t of the heating wire 131, within the plane (i.e., within the X-Y plane) on which the heating wire 131 extends; however, arranging the thermostat 160 in a position surrounded by the folded parts 131t as shown in FIG. 14 is preferable to arranging the thermostat 160 in a position interposed between the linear parts 131r. When the thermostat 160 is arranged in a position surrounded by the folded parts 131t, a larger area around the thermostat 160 is surrounded by the heating wire 131. Accordingly, because the heating wire 131 positioned around the thermostat 160 acts like a regulating member to regulate moving of the thermostat 160 in the X-axis direction and the Y-axis direction, it is possible to better prevent the position of the thermostat 160 from being displaced, which may occur at the time of attaching the jacket heater 100 or at the time of servicing or inspecting the jacket heater 100. With this configuration, the thermostat 160 is able to continuously maintain an accurate temperature detection function.

It is sufficient as long as the temperature sensor 150 and the thermostat 160 are positioned so that the temperature detection points (the temperature detection point 151 and the temperature detection unit 160a) do not overlap with the heating wire 131 in the Z-axis direction. Thus, it is acceptable even if the sections other than the temperature detection points are arranged so as to overlap with the heating wire 131. From the viewpoint of detecting the temperature more accurately, it is desirable to arrange the temperature sensor 150 so that, as shown in FIG. 14, none of the sections exposed to the inner surface of the inner layer 110, including the temperature detection point 151 (i.e., the sections of the temperature detection point 151 and the cable part 152 that are exposed to the inner surface of the inner layer 110) overlaps with the heating wire 131 in the Z-axis direction. Further, although FIG. 14 shows an example in which the temperature detection point 151 of the temperature sensor 150 is exposed from the inner surface of the inner layer 110, the temperature detection point 151 of the temperature sensor 150 may be positioned between the inner layer 110 and the heat generation layer 130. In that situation, it is desirable to ensure an arrangement in which none of the sections positioned between the inner layer 110 and the heat generation layer 130, including the temperature detection point 151 (i.e., the sections of the temperature detection point 151 and the cable part 152 that are positioned between the inner layer 110 and the heat generation layer 130) overlaps with the heating wire 131 in the Z-axis direction.

Further, possible positional relationships between the temperature sensor 150 and the thermostat 160 are not particularly limited, as long as the temperature detection points (the temperature detection point 151 and the temperature detection unit 160a) do not overlap with the heating wire 131 in the Z-axis direction. For example, the temperature sensor 150 and the thermostat 160 may be arranged side by side in the Y-axis direction as shown in FIG. 14 or may be arranged side by side in the X-axis direction. Further, the temperature sensor 150 and the thermostat 160 do not necessarily need to be arranged side by side in the X-axis direction or the Y-axis direction.

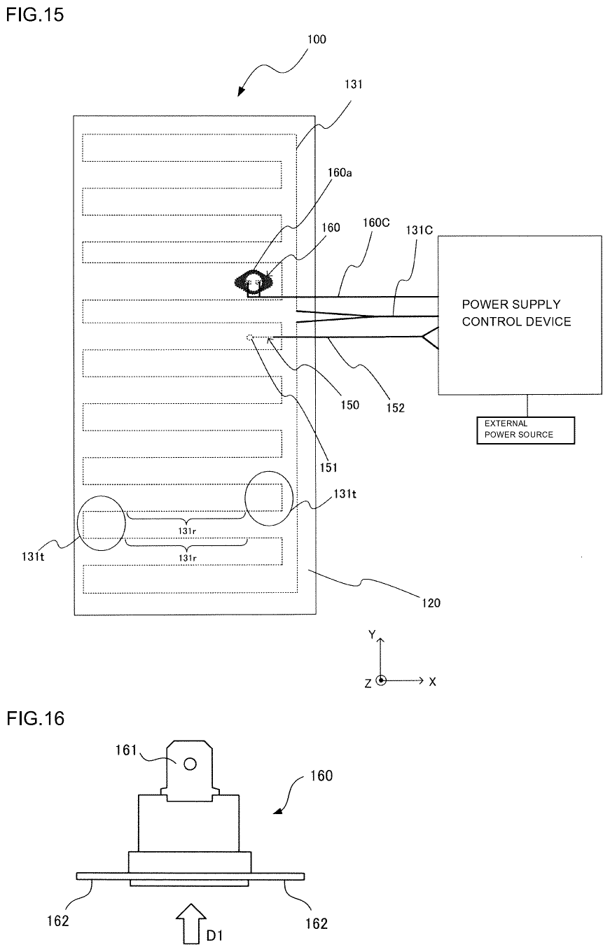

Next, a method for using the jacket heater according to the present embodiment will be explained, with reference to FIG. 15. As shown in FIG. 15, the jacket heater 100 according to the present embodiment may be used while being connected to a power supply control device connected to an external power source. More specifically, the jacket heater 100 may be used while being connected to the power supply control device, via the heating wire cable 131C connected to the heating wire 131, the cable part 152 of the temperature sensor 150, and the thermostat cable 160C connected to the thermostat 160.

The power supply control device is configured to supply the power to the heating wire 131 via the heating wire cable 131C. As a result of the power being supplied to the heating wire 131, the heating wire 131 is heated. Further, by receiving the electrical signal transmitted via the cable part 152 of the temperature sensor 150, the power supply control device judges whether or not the temperature of the measured object (the pipe P) obtained from the electrical signal is within the prescribed range. When it is determined that the temperature of the measured object is within the prescribed range, the power supply control device exercises the power supply control on the heating wire 131 so that the temperature of the heated object is maintained at that temperature. On the contrary, when it is determined that the temperature of the measured object (the pipe P) is higher than the prescribed range, the power supply control device exercises power supply control on the heating wire 131 so that the temperature of the heated object (the pipe P) becomes lower than the present temperature. When it is determined that the temperature of the measured object (the pipe P) is lower than the prescribed range, the power supply control device exercises power supply control on the heating wire 131 so that the temperature of the heated object (the pipe P) becomes higher than the present temperature.

Further, the power supply control device supplies power to the thermostat 160 via the thermostat cable 160C. When the temperature of the measured object (the pipe P) has risen and reached the prescribed level, the thermostat 160 goes into operation so as to block the electrical connection between the power supply control device and the thermostat 160. When the electrical connection between the power supply control device and the thermostat 160 is blocked, the power supply control device determines that the temperature of the measured object (the pipe P) has exceeded the prescribed level, stops exercising the power supply control based on the temperature of the pipe P measured by the temperature sensor 150, and exercises control so as to stop the power supply to the heating wire 131. After the power supply to the heating wire 131 is stopped, when the thermostat 160 is cooled so that the heated object (the pipe P) has reached a temperature lower than the prescribed level, the electrical connection between the power supply control device and the thermostat 160 is restored. When the electrical connection between the power supply control device and the thermostat 160 is restored, the power supply control device determines that the temperature of the measured object (the pipe P) has become lower than the prescribed level and resumes exercising the power supply control based on the temperature of the pipe P measured by the temperature sensor 150.

By using the jacket heater 100 of the present embodiment while being connected to the power supply control device described above, it is possible to adjust the temperature of the heated object while detecting the temperature of the heated object. Consequently, it is possible to maintain the heated object in the desired temperature range.

Further, possible power supply control schemes exercised by the power supply control device are not limited to the power supply control described above. It is also acceptable to use any power supply control schemes hitherto known publicly. In addition, although FIG. 15 shows the example in which the electrical circuit is provided between the thermostat 160 and the power supply control device (the external power source), separately from the electrical circuit between the heating wire 131 and the power supply control device (the external power source), it is not necessarily required to provide the electrical circuit between the thermostat 160 and the power supply control device (the external power source). In that situation, the thermostat 160 shall be connected in series to an electrical circuit including the heating wire 131 and the power supply control device (the external power source). The thermostat 160 connected in series to the electrical circuit including the heating wire 131 and the power supply control device (the external power source) goes into operation when the temperature of the measured object (the pipe P) has risen and reached the prescribed level so as to block the electrical connection of the electrical circuit including the heating wire and the power supply control device (the external power source), so that the power supply to the heating wire 131 is stopped. When the temperature of the measured object drops and becomes lower than the second prescribed temperature lower than the prescribed level, the thermostat 160 goes into operation, so that the electrical connection of the electrical circuit including the heating wire and the power supply control device (the external power source) is restored, and the power supply to the heating wire 131 is resumed. In this manner, when the thermostat 160 is connected in series to the electrical circuit including the heating wire and the power supply control device (the external power source), it is possible to exercise the temperature control based on the temperature detected by the thermostat 160, without the need to provide an electrical circuit between the thermostat 160 and the power supply control device (the external power source) separately from the electrical circuit provided between the heating wire 131 and the power supply control device (the external power source). In that situation, the thermostat 160 functions not only as a temperature sensor, but also as a power supply control device.

Further, the power supply control described above is an example of power supply control using the thermostat 160 of the automatic restoration type; however, in the situations where the thermostat 160 of a manual restoration type where the blocked electrical connection is restored manually or the thermostat 160 of a one-shot type characterized in that the second prescribed temperature being lower than the prescribed temperature at which the electrical connection is blocked is lower than a room temperature is used as the thermostat 160, it is possible to exercise power supply control in accordance with restoration conditions for the electrical connection.

In the jacket heater 100 according to the present embodiment described above, the temperature detection points (the temperature detection point 151 and the temperature detection unit 160a) of the temperature sensor 150 and the thermostat 160 are provided in the positions that do not overlap with the heating wire 131, in the direction perpendicular to the contact surface CS between the pipe P serving as the heated object and the inner layer 110. Consequently, the jacket heater 100 according to the present embodiment is able to increase the distance between the heating wire 131 and the temperature detection points, as compared to a jacket heater in which the temperature detection points overlap with the heating wire 131 in the direction perpendicular to the contact surface CS. As a result, the temperature sensor 150 (and the thermostat 160) do not easily get impacted by the heat generated from the heating wire 131. Consequently, in addition to the characteristics of the first embodiment, the jacket heater 100 according to the present embodiment has another characteristic where the temperature detection point of the temperature sensor 150 is provided in the position that does not overlap in the direction perpendicular to the contact surface CS between the heated object (the pipe P) and the inner layer 110. Thus, in addition to the advantageous effects where a wiring disconnection does not easily occur in the cable part 152, and the position of the temperature detection point 151 is not easily displaced, it is possible to detect the temperature of the measured object more accurately. Furthermore, because the jacket heater 100 according to the present embodiment is able to detect the temperature of the measured object more accurately, when the jacket heater 100 is used while being connected to the power supply control mechanism, it is possible to exercise appropriate power supply control and to also maintain the heated object within the desirable temperature range.

Further, the jacket heater 100 according to the present embodiment shown in FIGS. 10 to 15 includes the two sensors for detecting the temperature, namely, the temperature sensor 150 and the thermostat 160; however, as long as at least the temperature sensor 150 is included, the quantity of the sensors for detecting the temperature is not particularly limited. The quantity of the sensors for detecting the temperature may be one or may be three or more. Even in those situations, as long as the temperature detection point of the one or more sensors for detecting the temperature is provided in a position that does not overlap with the heating wire 131 in the direction perpendicular to the contact surface CS between the pipe P serving as the heated object and the inner layer 110, it is possible to increase the distance between the heating wire 131 and the temperature detection point, as compared to a jacket heater in which the temperature detection point of one or more sensors for detecting the temperature overlaps with the heating wire 131 in the direction perpendicular to the contact surface CS. Accordingly, even when the quantity of the sensors for detecting the temperature is one or three or more, the impact of the heat generated from the heating wire 131 is not easily imposed, and it is therefore possible to detect the temperature of the measured object more accurately. Further, because it is possible to detect the temperature of the measured object more accurately, it is possible to maintain the heated object within the desirable temperature range, by using the jacket heater while being connected to the power supply control mechanism.

### Third Embodiment

Next, a jacket heater according to a third embodiment of the present invention will be explained.

Similarly to the jacket heater 100 according to the first embodiment, the jacket heater 100 according to the present embodiment is structured so that a partial section of the cable part 152 of the temperature sensor 150 is positioned on the aforementioned bypassing path. In addition, another characteristic lies that the thermostat 160 is provided, and the thermal insulation layer 140 is formed so as to be fitted along the exterior shape of the thermostat 160, while an accommodation part forming a space for accommodating the thermostat 160 therein is provided.

Next, the jacket heater 100 according to the present embodiment will be explained, with reference to FIGS. 16 to 21. In this situation, some of the constituent elements described for the jacket heater 100 according to the first embodiment will be referred to by using the same reference characters, and detailed explanations thereof will be omitted.

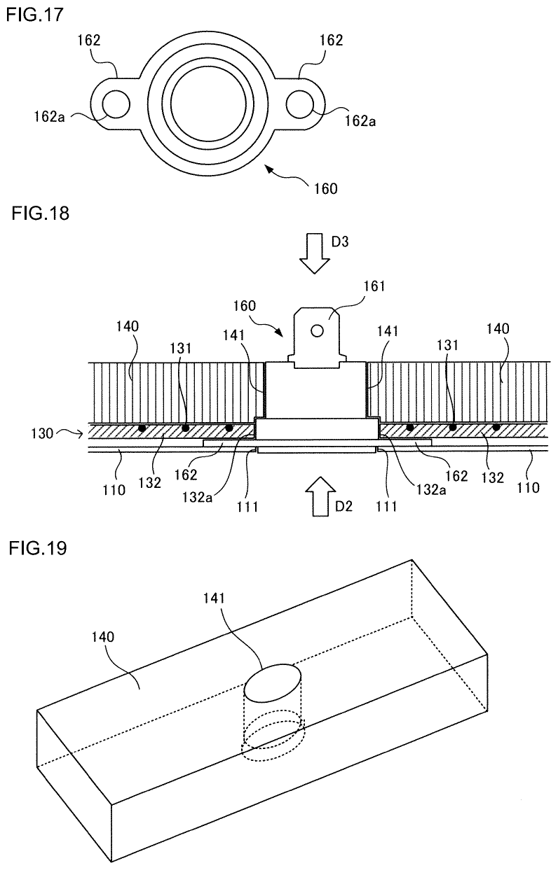

The jacket heater 100 according to the present embodiment is provided with the thermostat 160 shown in FIG. 16 and FIG. 17. The thermostat 160 is a thermostat of a bimetal type and is used for switching between an electrically conductive state and an electrically non-conductive state of the heating wire 131 in accordance with temperature of the pipe P. The thermostat 160 is positioned so as to be in contact with the outer circumferential surface of the pipe P, so that heat of the pipe P is transferred to the thermostat 160. With this configuration, it is possible to cause the thermostat 160 to operate in accordance with the temperature of the pipe P.

A structure (an example) of the thermostat 160 will be explained, with reference to FIG. 16 and FIG. 17. FIG. 16 is a side view of the thermostat 160. FIG. 17 is a drawing (a bottom view) of the thermostat 160 as viewed in the direction of the arrow D1 in FIG. 16. However, possible structures of the thermostat 160 are not limited to the structure shown in FIG. 16 and FIG. 17.

Provided inside the thermostat 160 is a bimetal (not shown). As a result of being deformed in accordance with temperature, the bimetal controls a switch between an ON state and an OFF state. When the thermostat 160 is connected in series to an electrical circuit including the heating wire 131 and an external power source, the heating wire 131 is allowed to be electrically conductive when the switch is in the ON state, whereas the electrical conductivity of the heating wire 131 is blocked when the switch is in the OFF state.

The thermostat 160 includes a pair of terminals 161 connected to the heating wire 131 and a pair of flanges 162 for fixing the thermostat 160. The pair of terminals 161 are connected to the switch turned on/off by the bimetal described above. As shown in FIG. 17, the flanges 162 each have an opening part 162a formed therein, so that it is possible to fix the thermostat 160 onto the supporting member 132, by having a thread sewn onto the supporting member 132, while putting the thread through the opening parts 162a.

In the present embodiment, the thermostat 160 is fixed onto the supporting member 132 by using the thread; however, possible embodiments are not limited to this example. In other words, it is sufficient as long as it is possible to fix the thermostat 160 to the supporting member 132. For example, it is acceptable to fix the flanges 162 of the thermostat 160 to the supporting member 132 by using an adhesive agent. Further, even when the thermostat 160 is not provided with the flanges 162, it is possible to fix the thermostat 160 to the supporting member 132, by using publicly-known fixation means (e.g., an adhesive agent).

FIG. 18 is a cross-sectional view showing a state in which the thermostat 160 is fixed to the supporting member 132. In this situation, the outer layer 120 is omitted from FIG. 18. The supporting member 132 has formed therein an opening part 132a to be penetrated by the thermostat 160. The inner layer 110 also has formed therein an opening part 111 to be penetrated by the thermostat 160. With this configuration, it is possible to bring the thermostat 160 into contact with the outer circumferential surface of the pipe P.

The thermal insulation layer 140 is provided with an accommodation part 141 to accommodate a part of the thermostat 160 therein. As shown in FIG. 19, the accommodation part 141 is a through hole penetrating the thermal insulation layer 140 and is formed to have a shape fitted along the exterior shape of the thermostat 160. In this situation, the accommodation part 141 does not need to be strictly fitted along the exterior shape of the thermostat 160. It is sufficient as long as at least a part of the accommodation part 141 is in contact with the external surface of the thermostat 160, so as to be able to determine the position of the thermostat 160.

As shown in FIG. 18, the flanges 162 of the thermostat 160 are positioned between the supporting member 132 and the inner layer 110 and, as explained above, are sewn onto the supporting member 132. It is possible to determine the position of the thermostat 160, also by sewing the flanges 162 onto the supporting member 132.

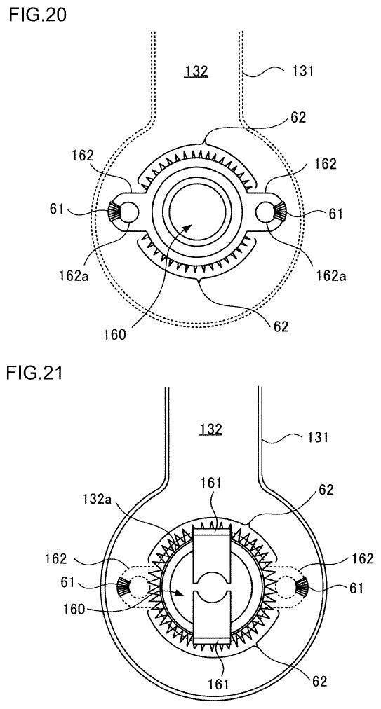

FIG. 20 shows a state (an example) in which the flanges 162 are sewn onto the supporting member 132 and is a drawing of the thermostat 160 as viewed in the direction of the arrow D2 in FIG. 18. The inner layer 110 shown in FIG. 18 is omitted from FIG. 20. Further, FIG. 21 is a drawing of the thermostat 160 as viewed in the direction of the arrow D3 in FIG. 18. The outer layer 120 and the thermal insulation layer 140 are omitted from FIG. 21.

As shown in FIG. 20, a thread 61 is put through the opening parts 162a of the flanges 162, so as to have the thread 61 sewn onto the supporting member 132. In addition, a reinforcement thread 62 is sewn onto the supporting member 132 along the edge of the opening part 132a, so as to ensure strength of the opening part 132a.

As shown in FIG. 21, the heating wire 131 is arranged with the supporting member 132 so as to avoid a region where the thermostat 160 is provided. More specifically, the heating wire 131 is arranged along the opening part 132a in a certain position of the supporting member 132 apart from the opening part 132a by a prescribed distance. For example, it is possible to fix the heating wire 131 onto the supporting member 132, by having a thread (not shown) sewn onto the supporting member 132 in such a manner that the heating wire 131 is pressed onto the supporting member 132 by the thread.

By arranging the supporting member 132 as described above, it is possible to ensure that the heat generated from the heating wire 131 does not easily get transferred to the thermostat 160, and it is therefore possible to prevent malfunctioning of the thermostat 160 that may be caused by the heat from the heating wire 131.

Further, in a certain region of the supporting member 132 where the thermostat 160 is not positioned, it is possible to arrange the heating wire 131 according to a prescribed arrangement pattern, so that the heat from the heating wire 131 is easily transferred to the entirety of the pipe P. For example, on the surface of the supporting member 132, it is possible to arrange the heating wire 131 so that the heating wire 131 is folded back and forth so as to form rows positioned at prescribed intervals. In this situation, in an attempt to cause the heat from the heating wire 131 to be efficiently transferred to the entirety of the pipe P, there is a tendency that the intervals between the rows of the heating wire 131 described above become smaller than the outside diameter of the thermostat 160. In that situation, to avoid interference between the heating wire 131 and the thermostat 160, significance lies in that the heating wire 131 is arranged along the opening part 132a as described above.

According to the present embodiment, the accommodation part 141 of the thermal insulation layer 140 is formed so as to be fitted along the exterior shape of the thermostat 160 and to accommodate the thermostat 160 therein and is thus able to determine the position of the thermostat 160 in the jacket heater 100. With this configuration, it is possible to bring the thermostat 160 into contact with the pipe P without the positional displacement, and it is therefore possible to efficiently cause the heat of the pipe P to be transferred to the thermostat 160. Further, it is possible to cause the thermostat 160 to operate appropriately, in accordance with the temperature of the pipe P. Furthermore, because the jacket heater 100 according to the present embodiment has the characteristics of the first embodiment, a wiring disconnection does not easily occur in the cable part 152 of the temperature sensor 150, and the position of the temperature detection point 151 is not easily displaced.

Further, although the accommodation part 141 penetrates the thermal insulation layer 140 in the present embodiment, possible embodiments are not limited to this example. More specifically, the accommodation part 141 may be a recessed part that opens toward the pipe P, without penetrating the thermal insulation layer 140. The lateral face of the recessed part is formed to have a shape fitted along an outer lateral face of the thermostat 160. Even when the thermostat 160 is accommodated in such a recessed part, it is possible to achieve the advantageous effects of the present embodiment described above. When the thermostat 160 is accommodated in such a recessed part, because the terminals 161 of the thermostat 160 are positioned on the bottom face side of the recessed part, it is acceptable to form, in the thermal insulation layer 140, a passage for putting through the heating wire 131 connected to the terminals 161.

### REFERENCE SIGNS LIST

100 jacket heater
110 inner layer
120 outer layer
130 heat generation layer
131 heating wire
131C heating wire cable
132 supporting member
140 thermal insulation layer
150 temperature sensor
151 temperature detection point
152 cable part
152a thermal insulation layer derivation part
152b outer layer introduction part
152c heat generation layer derivation part
152d thermal insulation layer introduction part
152e inner layer derivation part
152f heat generation layer introduction part
160 thermostat
160a temperature detection unit
160b contraption part
S slit
P pipe
CS contact surface

1. A jacket heater that is to be attached to a heated object for use, comprising:
an inner layer being in contact with the heated object;
an outer layer;
a heat generation layer and a thermal insulation layer provided between the inner layer and the outer layer; and
a temperature sensor including a temperature detection point exposed to an inner surface of the inner layer being in contact with the heated object and a cable part extending from the temperature detection point, wherein
the cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.

2. The jacket heater according to claim 1, wherein
the thermal insulation layer includes a first thermal insulation layer provided between the heat generation layer and the outer layer and a second thermal insulation layer provided between the first thermal insulation layer and a side of the outer layer, and
the section of the cable part from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the inner layer, the heat generation layer, the first thermal insulation layer, the second thermal insulation layer, and the outer layer.

3. A jacket heater that is to be attached to a heated object for use, comprising:
an inner layer being in contact with the heated object;
an outer layer;
a heat generation layer and a thermal insulation layer provided between the inner layer and the outer layer; and
a temperature sensor including a temperature detection point positioned between the inner layer and the heat generation layer and a cable part extending from the temperature detection point, wherein
the cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.

4. The jacket heater according to claim 3, wherein
the thermal insulation layer includes a first thermal insulation layer provided between the heat generation layer and the outer layer and a second thermal insulation layer provided between the first thermal insulation layer and a side of the outer layer, and
the section of the cable part from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the heat generation layer, the first thermal insulation layer, the second thermal insulation layer, and the outer layer.

5. The jacket heater according to claim 1, wherein
a section of the cable part positioned in an inter-layer space between the outer layer and the thermal insulation layer is positioned on the path bypassing the linear path connecting the derivation part to the introduction part.

6. The jacket heater according to claim 1, wherein
the heat generation layer includes a heating wire as a heat source, and
a heating wire cable connected to the heating wire penetrates the thermal insulation layer and the outer layer, starting with the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.

7. The jacket heater according to claim 6, wherein
the thermal insulation layer includes a first thermal insulation layer provided between the heat generation layer and the outer layer and a second thermal insulation layer provided between the first thermal insulation layer and a side of the outer layer, and
the section of the heating wire cable from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the heat generation layer, the first thermal insulation layer, the second thermal insulation layer, and the outer layer.

8. The jacket heater according to claim 1, wherein
the temperature sensor is one of a thermocouple and a resistance thermometer.

9. A method for manufacturing a jacket heater that is to be attached to a heated object for use, comprising:
a step of forming a laminated body including an inner layer being in contact with the heated object, an outer layer, as well as a heat generation layer and a thermal insulation layer provided between the inner layer and the outer layer, the laminated body having fixed thereto a temperature sensor including a temperature detection point and a cable part extending from the temperature detection point, wherein
the temperature detection point is exposed to an inner surface of the inner layer, and
the cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.

10. A method for manufacturing a jacket heater that is to be attached to a heated object for use, comprising:
a step of forming a laminated body including an inner layer being in contact with the heated object, an outer layer, as well as a heat generation layer and a thermal insulation layer provided between the inner layer and the outer layer, the laminated body having fixed thereto a temperature sensor including a temperature detection point and a cable part extending from the temperature detection point, wherein
the temperature detection point is positioned between the inner layer and the heat generation layer, and
the cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.

11. A heating unit that covers a pipe and heats an inside of the pipe, comprising:
an inner layer being in contact with a heated object;
an outer layer;
a heat generation layer and a thermal insulation layer provided between the inner layer and the outer layer; and
a temperature sensor including a temperature detection point exposed to an inner surface of the inner layer being in contact with the heated object and a cable part extending from the temperature detection point, wherein
the cable part penetrates the inner layer, the heat generation layer, the thermal insulation layer, and the outer layer, starting with the inner layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the inner layer, the heat generation layer, the thermal insulation layer, and the outer layer.

12. A heating unit that covers a pipe and heats an inside of the pipe, comprising:
an inner layer being in contact with a heated object;
an outer layer;
a heat generation layer and a thermal insulation layer provided between the inner layer and the outer layer; and
a temperature sensor including a temperature detection point positioned between the inner layer and the heat generation layer and a cable part extending from the temperature detection point, wherein
the cable part penetrates the heat generation layer, the thermal insulation layer, and the outer layer, starting with a space between the inner layer and the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer

13. The jacket heater according to claim 3, wherein
a section of the cable part positioned in an inter-layer space between the outer layer and the thermal insulation layer is positioned on the path bypassing the linear path connecting the derivation part to the introduction part.

14. The jacket heater according to claim 3, wherein
the heat generation layer includes a heating wire as a heat source, and
a heating wire cable connected to the heating wire penetrates the thermal insulation layer and the outer layer, starting with the heat generation layer toward the outer layer, while a section from a derivation part derived from one layer of adjacently-positioned layers to an introduction part introduced to the other layer of the adjacently-positioned layers is positioned on a path bypassing a linear path connecting the derivation part to the introduction part, in a space between the adjacently-positioned layers including at least one of the heat generation layer, the thermal insulation layer, and the outer layer.

15. The jacket heater according to claim 14, wherein
the thermal insulation layer includes a first thermal insulation layer provided between the heat generation layer and the outer layer and a second thermal insulation layer provided between the first thermal insulation layer and a side of the outer layer, and
the section of the heating wire cable from the derivation part derived from the one layer of adjacently-positioned layers to the introduction part introduced to the other layer of the adjacently-positioned layers is positioned on the path bypassing the linear path connecting the derivation part to the introduction part, in a space between the adjacently-positioned layers including at least one of the heat generation layer, the first thermal insulation layer, the second thermal insulation layer, and the outer layer.

16. The jacket heater according to claim 3, wherein
the temperature sensor is one of a thermocouple and a resistance thermometer.
